(19) United States
(12) Patent Application Publication
(10) Pub. No.: US 2010/0097760 A1
(43) Pub. Date: Apr. 22, 2010

(54) Impingement Cooling

(76) Inventors: Kaveh Azar, Westwood, MA (US); Bahman Tavassoli Hojati, Norton, MA (US)

Correspondence Address: Amit K. Singh, 1075 Salem Street, North Andover, MA, 01845-4908, US

(21) Appl. No.: 12/254,125

(22) Filed: Oct. 20, 2008

(51) Int. Cl. H05K 7/20; F28D 15/00

(52) U.S. Cl. 361/695; 165/104.11; 361/689

(57) ABSTRACT

An apparatus and a method for impingement cooling. The apparatus may include a plenum having a fluid. The plenum may be configured to contact a plate. A duct may be attached to the plate, wherein the duct may include a hole configured to pass the fluid, such as an air or a gas. A heat source, such as an electric or electronic component, may be located proximate to the hole, such as on a printed circuit board. The hole may be configured to make a contact between the fluid and the heat source. Methods to make the foregoing structure are also described.

### BACKGROUND

1. Field

This disclosure is generally related to impingement cooling and in particular to impingement cooling of electric and electronic circuits, such as electric and electronic circuits located in an enclosure.

2. Description of Related Art

Typical electronic circuitry requires some form of cooling to avoid component damage or premature component failure. With an increase in component power dissipation and shrinking real estate on a printed circuit board (PCB) for a heat sink, conventional air cooling by forcing air substantially parallel to the PCB is approaching its effective limit.

FIG. 1 is a cross-section view of a prior art apparatus 100 for cooling an electronic equipment. The apparatus 100 is a 5 slot ATCA (Advanced Telecom Computing Architecture) chassis. Input air 110 is drawn by one or more fans 108 (two fans shown in FIG. 1). Air 112 is shown in contact with components 104 attached to a printed circuit board (PCB) 106. Exhaust air 102 leaves the components 104 and the PCB 106 thereby attaining a cooling of the components 104 attached to the PCB 106.

### BRIEF SUMMARY

Embodiments of the present disclosure provide an apparatus and a method for impingement cooling. The present disclosure teaches how to make an apparatus for impingement cooling which may be applied to electric or electronic equipment.

Briefly described, in architecture, one embodiment of the system, among others, can be implemented as follows.

An apparatus may include a plenum having a fluid, such as air or a gas. The plenum may be configured to contact a plate. A duct may be attached to the plate, wherein the duct may include a hole configured to pass the fluid. The hole may be in an impingement plate included in the duct. A heat source, such as an electric or electronic component, may be located proximate to the hole. The hole may be configured to make a contact between the fluid and the heat source.

The present disclosure can also be viewed as providing a method, e.g., of making an apparatus for electrical or electronic cooling. The method may include providing a plenum having a fluid, such as air or a gas, coupling a duct to the plenum, including a hole in the duct to pass the fluid, locating a heat source proximate to the hole, and configuring the hole to direct the fluid towards the heat source to modify a temperature of the heat source.

Other systems, apparatus, methods, features, and advantages of the present invention will be, or will become apparent, to a person having ordinary skill in the art upon examination of the following drawings and detailed description. It is intended that all such additional systems, apparatus, methods, features, and advantages included within this description, be within the scope of the present disclosure, and be protected by the accompanying claims.

### BRIEF DESCRIPTION OF THE SEVERAL VIEWS OF THE DRAWINGS

Many aspects of the disclosure can be better understood with reference to the following drawings. Components in the drawings are not necessarily to scale, emphasis instead being placed upon clearly illustrating principles of the present invention. Moreover, in the drawing, like-referenced numerals designate corresponding parts throughout the several views.

FIG. 1 is a cross-section view of a prior art apparatus for cooling an electronic equipment.

FIG. 2 is a cross-section view of an embodiment of the present disclosure.

FIG. 3 is a view of a portion of FIG. 2.

FIG. 4 is a cross-section view of another embodiment of the present disclosure.

FIG. 5 is a cross-section view of another embodiment of the present disclosure.

FIG. 6 is a perspective view of the embodiments of FIGS. 2 and 4 of the present disclosure.

FIG. 7 is a cross-section view of another embodiment of the present disclosure.

FIG. 8 is a perspective view of air path in an enclosure.

FIGS. 9-13 illustrate exemplary holes of the present disclosure.

FIG. 14 is a cross-section view of another embodiment of the present disclosure.

FIG. 15 is a cross-section view of another embodiment of the present disclosure.

FIG. 16 is a flowchart of an embodiment of a method the present disclosure.

FIG. 17 is an experimental setup for the present disclosure.

FIG. 18 is a plot of a result of the test setup of FIG. 17.

FIG. 19 is a cross-section view of another embodiment of the present disclosure.

FIG. 20 is a view of a portion of FIG. 19.

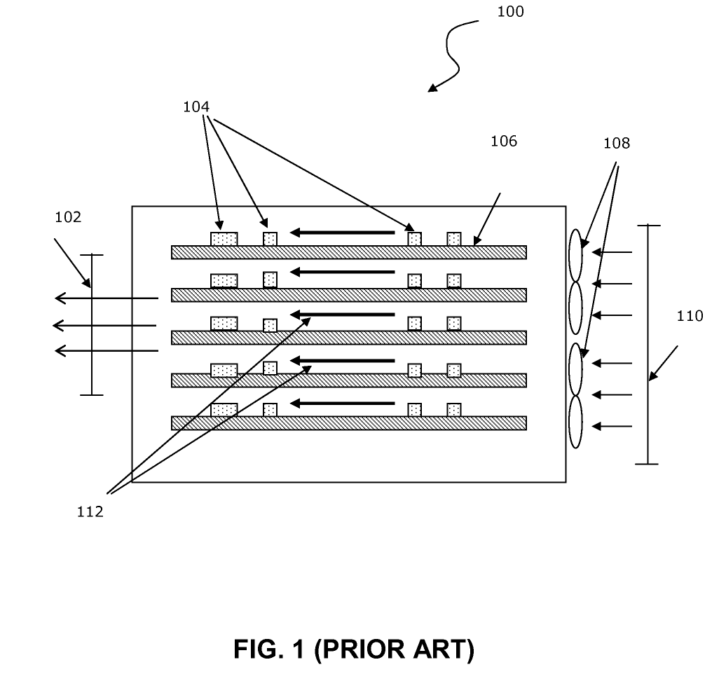

### DETAILED DESCRIPTION

The present disclosure relates to a system and method for cooling electric and electronic equipment.

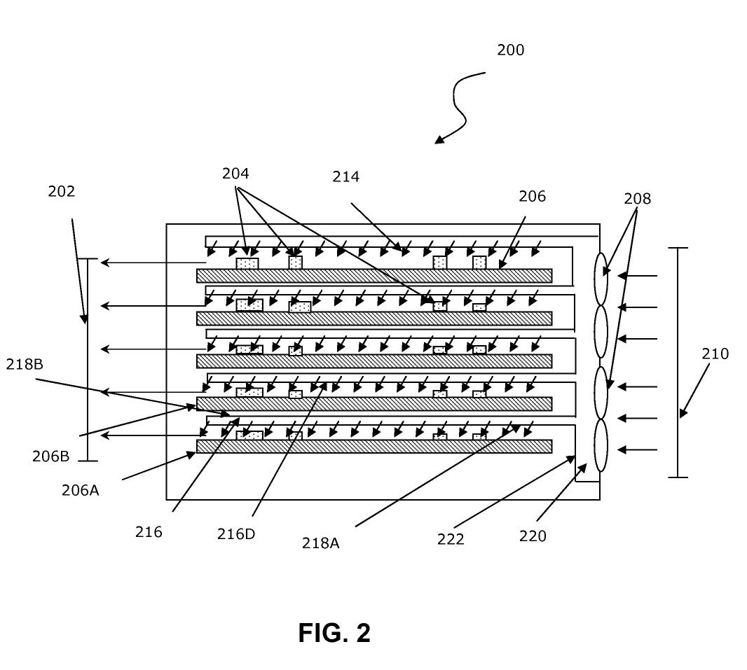

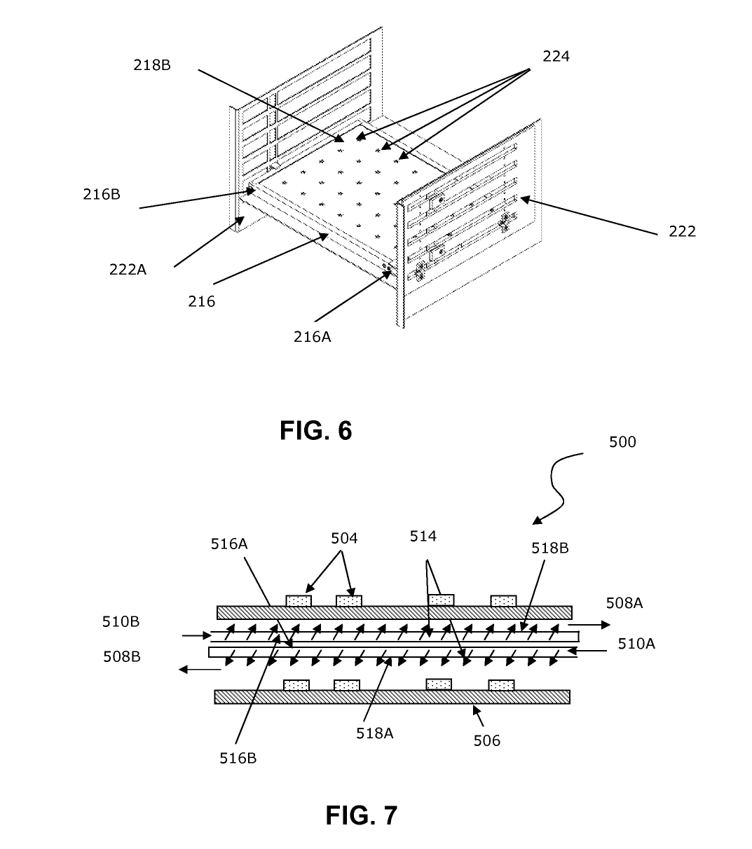

FIG. 2 is a cross-section view of an embodiment of the present disclosure. FIG. 2 illustrates a system 200 which may include an apparatus having a plenum 220. An example of the system 200 may be a 5-slot ATCA. The plenum 220 may have a fluid, such as an input air 210, forced through a fan 208 (a pair of fans 208 shown) and the plenum 220 may be configured to contact a plate 222. A duct 216, such as an impingement duct, may be attached to the plate 222, wherein the duct 216 may include a hole configured to pass the input air 210. The hole, more clearly shown in FIG. 6 described below, may be in an impingement plate, described below, included in the duct. The holes 940, 1040, 1140, 1240, and 1340 are more clearly shown in FIGS. 9-13 described below. A heat source, such as a component 204 being of an electric or electronic type, may be located proximate to the hole and the hole may be configured to make a contact between the input air 210 and the heat source, such as the component 204. An exhaust air 202 may accomplish cooling the component 204 and leave the system 200.

In the system 200, the apparatus may include a plurality of ducts 216, 216D attached to the plate 222. The duct 216 may include a plurality of holes 940, 1040, 1140, 1240, and 1340 shown in FIGS. 9-13 described below. A duct 216 may include a predetermined combination of the holes 940, 1040, 1140, 1240, and 1340 of FIGS. 9-13. The input air 210 may be a gas.

In the system 200, the apparatus may include a plurality of heat sources, such as a plurality of components 204 attached to an electric circuit substrate 206, the electric circuit substrate 206 may be located at a predetermined distance from the duct 216. An example of the electric circuit substrate 206 is a PCB. Further instances of the electric circuit substrate 206 may be a first PCB 206A and a second PCB 206B. The electric circuit substrate 206 may be coupled to one of a heat pipe and a vapor chamber (not shown). In the system 200, the apparatus may include an electric component which is conduction coupled to the electric circuit substrate 206.

As an alternative to the duct 216, 216D having one or more holes, the duct 216, 216D may include at least one impingement plate 218A. The at least one impingement plate 218A may include at least one hole. As described below, in an embodiment with a second impingement plate, a surface 218B of the duct 216 may include the second impingement plate.

In the system 200, the apparatus may include a plurality of heat sources 204 attached to an electric circuit substrate 206, the electric circuit substrate 206 may be oriented at an angle with respect to a direction of a flow of the fluid, such as the input air 210 or the exhaust air 202. The input air 210 may be coupled to one of a compressor and a fan. The input air 210 or the exhaust air 202 may have an intermittent flow. The intermittent flow may be accomplished by throttling the plenum 220, or the duct 216, or a hole (such as hole 224 shown in FIG. 6), or a nozzle (such as nozzle 860 shown in FIG. 15).

In the system 200, the apparatus may include the fluid, such as the input air 210, to be coupled to a controller (not shown). The controller may be configured to direct the fluid to a part of an electric circuit substrate 206 having one or more heat sources 204 in response to a change in a temperature of the part of the electric circuit substrate 206.

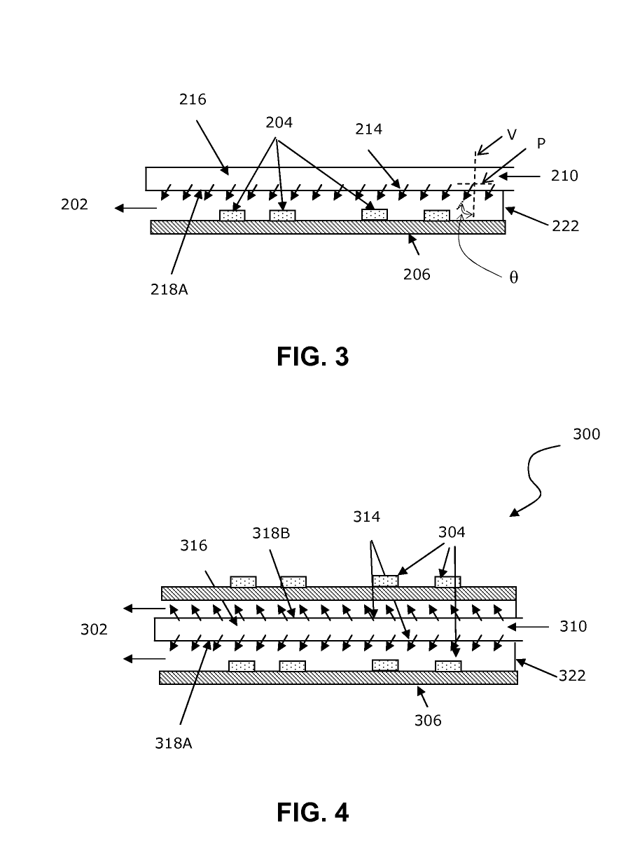

FIG. 3 is a view of a portion of FIG. 2. Input air 210 may be flowing into the duct 216. One or more components 204 may be attached to the electric circuit substrate 206. An impinged air 214 may be brought in contact with one or more components 204. The at least one impingement plate 218A may be attached to the duct 216. The exhaust air 202 may leave the electric circuit substrate 206. A plane of the duct 216 is indicated by a line P, a vertical line may be indicated by a line V, and an angle E shows an angle of a hole letting the impinged air 214 pass and contact the components 204.

FIG. 4 is a cross-section view of another embodiment of the present disclosure. An apparatus 300 may include an input air 310 flowing into a duct 316. An electric circuit substrate 306, such as a PCB, may include a component 304. The duct 316 may include a first impingement plate 318A and a second impingement plate 318B. The first impingement plate 318A and the second impingement plate 318B may each have one or more holes to let an impinged air 314 pass. As shown in FIG. 4, the impinged air 314 may come in contact with a side of the PCB having the component 304 and a side of another PCB opposite to the one having the component 304.

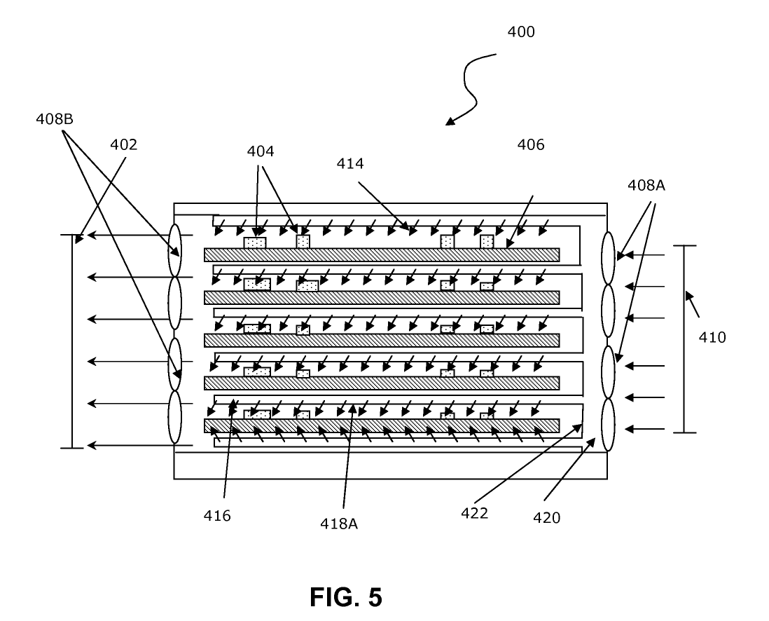

FIG. 5 is a cross-section view of another embodiment of the present disclosure. In an apparatus 400, a push pull fan tray system may be used to enhance a pressure. The apparatus 400 may be extended to include a pull-pull fan tray system or a push-push fan tray system. The apparatus 400 may include a plenum 420 and one or more fans 408A to push an input air 410 and one or more fans 408B to pull an exhaust air 402. One or more components 404 may be attached to a PCB 406 as an instance of an electric circuit substrate. An impinged air 414 may be directed towards the component 404 from one or more holes in a duct 416 attached to a plate 422. The duct 416 may include an impingement plate 418A.

In the apparatus 400, one or more ducts 416, the plenum 420 and a fan tray including the fans 408A may be in one piece. In a production mode, such apparatus 400 may allow an assembler to insert an assembled fan tray and the duct 416 into the ATCA and bolt the assembled fan tray appropriately, such as to a side of the ATCA.

FIG. 6 is a perspective view of the embodiments of FIGS. 2 and 4 of the present disclosure. The duct 216 may include a first end 216A and a second end 216B, wherein the first end 216A may be attached to a first plate 222 and the second end 216B may be attached to a second plate 222A. A surface 218B of the duct 216, which may include the second impingement plate, is shown having holes 224. The first plate 222 may be coupled (not shown in FIG. 6) to the second plate 222A in a manner known in the art. In another embodiment, the one or more ducts 216 may be attached to a supporting plate which may be fastened to a side of one or more rails. A fan tray and a plenum may be flush mounted with the plate 222. In another embodiment, the duct 216 may be individually attached to a PCB.

FIG. 7 is a cross-section view of another embodiment of the present disclosure. An apparatus 500 may include a first duct 516A and a second duct 516B. The first duct 516A may have a first impingement plate 518A and the second duct 516B may have a second impingement plate 518B. One or more components 504 may be attached to an electric circuit substrate 506, such a PCB. The one or more components 504 may be contacted by impinged air 514. The first duct 516A may have an input air 510A flowing in and an exhaust air 508B flowing out, for example, with respect to the plate 222, shown in FIG. 6. The second duct 516B may have an input air 510B flowing in and an exhaust air 508A flowing out, for example, with respect to the plate 222, shown in FIG. 6. The first duct 516A may be configured, such as by modifying one or more surfaces of the first duct 516A, to cause a flow of the fluid, such as the input air 510A, 510B in a direction towards the plate 222, shown in FIG. 6. The second duct 516B may be configured, such as by modifying one or more surfaces of the second duct 516B, to cause a flow of the fluid, such as the exhaust air 508A, 508B in a direction away from the plate 222, shown in FIG. 6. The aforementioned configuration may be similar to a counterflow heat exchanger.

A highly copperized PCB 206 and a good thermal coupling between components 504 and the PCB 506 may allow for a uniform high capacity impingement cooling, such as a jet impingement cooling.

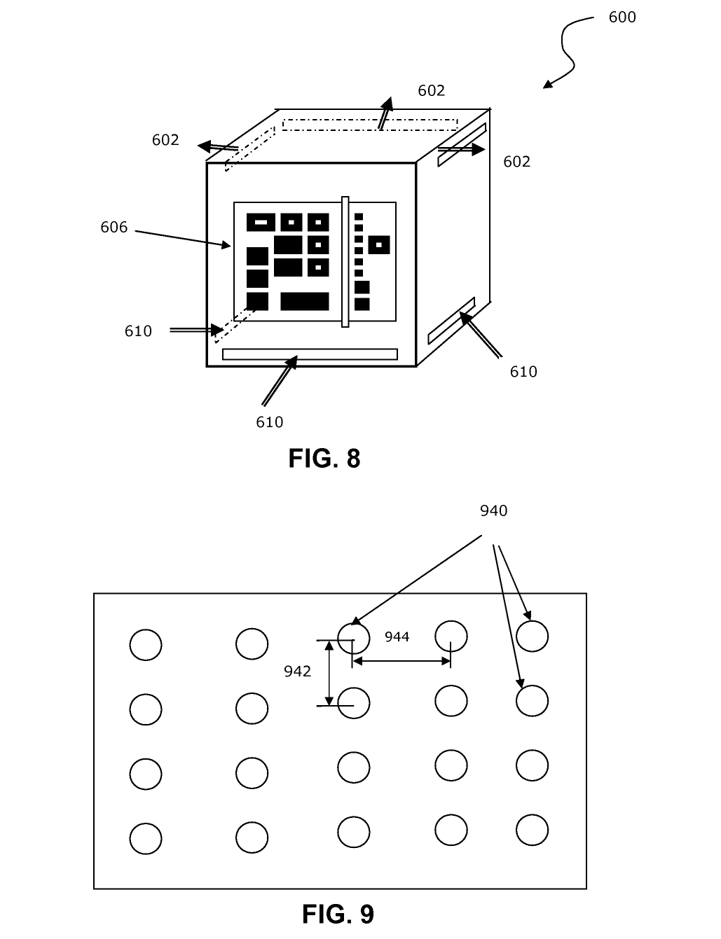

FIG. 8 is a perspective view of an air path in an enclosure 600. The enclosure 600 may be an ATCA or a μTCA (Micro Telecom Computing Architecture). The enclosure may have one or more PCBs 606 and an input air 610 entering the enclosure 600 and an exhaust air 602 leaving the enclosure 600. The one or more PCBS 606 may be oriented at any angle with respect to a direction of the input air 610. The one or more PCBS 606 may be oriented at any angle with respect to a direction of the exhaust air 602.

FIGS. 9-13 illustrate exemplary holes of the present disclosure. One or more holes described above may be at an angle with respect to a plane of the duct 216, for example, shown in FIG. 2.

FIG. 9 shows circular holes 940 which may be spaced at a predetermined variable distance 942 in a first direction and a predetermined variable distance 944 in a second direction. The aforementioned distances may be determined by a desired cooling performance.

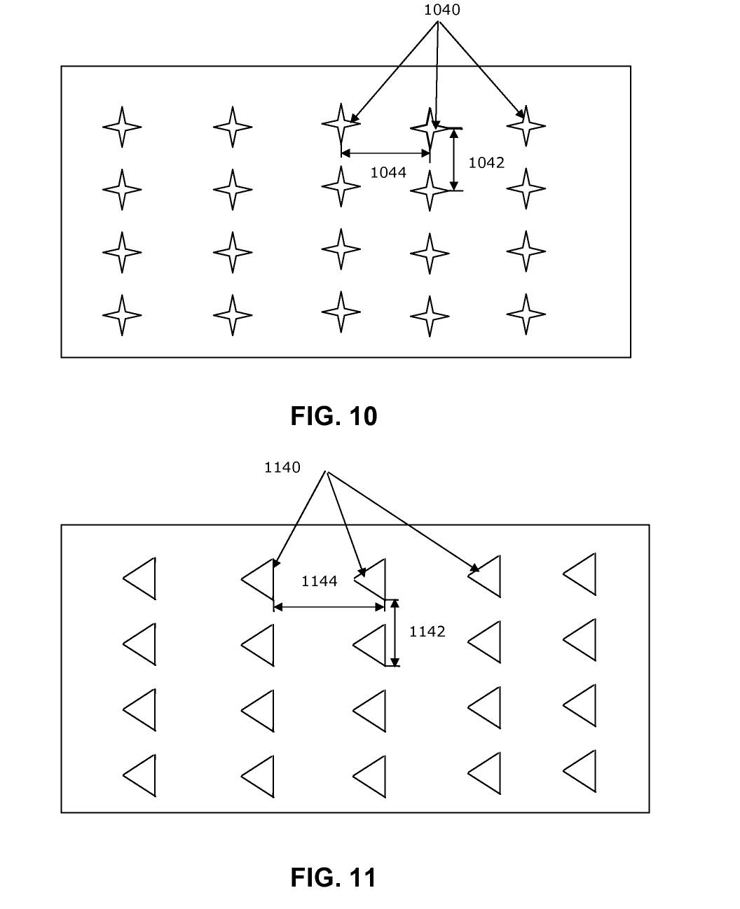

FIG. 10 shows star holes 1040 which may be spaced at a predetermined variable distance 1042 in a first direction and a predetermined variable distance 1044 in a second direction. The aforementioned distances may be determined by a desired cooling performance.

FIG. 11 shows triangular holes 1140 which may be spaced at a predetermined variable distance 1142 in a first direction and a predetermined variable distance 1144 in a second direction. The aforementioned distances may be determined by a desired cooling performance.

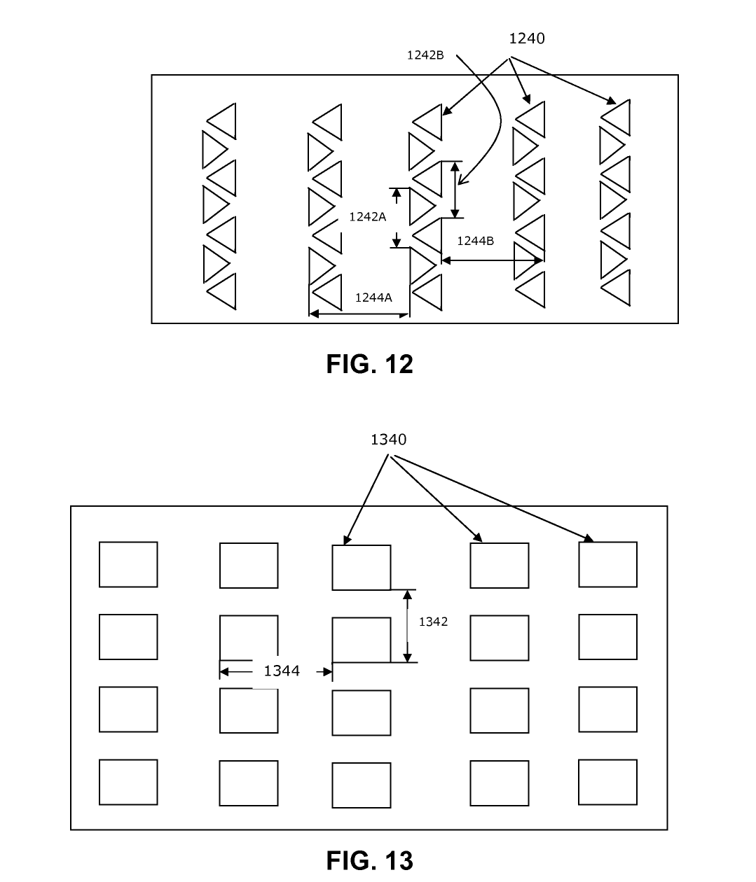

FIG. 12 shows opposing triangular holes 1240 which may be spaced at a predetermined variable distance 1242A in a first direction, a predetermined variable distance 1242B in a second direction, a predetermined variable distance 1244A in a third direction, and a predetermined variable distance 1244B in a fourth direction. The aforementioned distances may be determined by a desired cooling performance.

FIG. 13 shows rectangular holes 1340 which may be spaced at a predetermined variable distance 1342 in a first direction and a predetermined variable distance 1344 in a second direction. The aforementioned distances may be determined by a desired cooling performance.

The one or more holes shown in FIGS. 9-13 may have a predetermined size. The one or more holes shown in FIGS. 9-13 may have a predetermined shape.

Similar to the holes shown in FIGS. 9-13, the duct 216 of FIG. 2 may include a plurality of holes, the plurality of holes may have a plurality of sizes selected from a predetermined range of sizes. The plurality of holes may be located on the duct 216 at one of an equal interval between the plurality of holes and a variable interval between the plurality of holes.

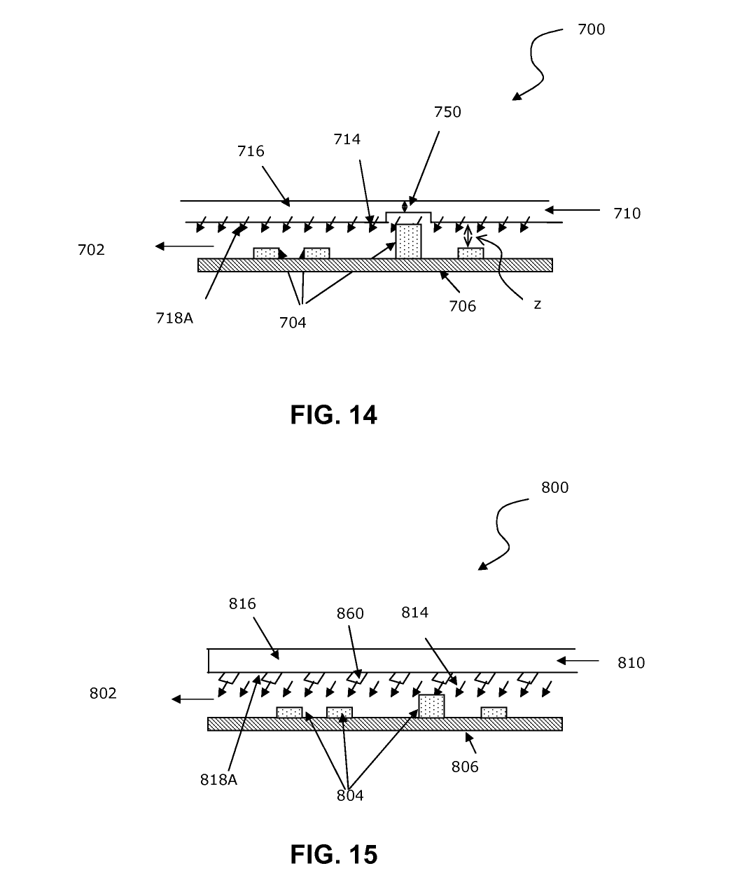

FIG. 14 is a cross-section view of another embodiment of the present disclosure. An apparatus 700 may include an input air 710 entering a duct 716 proximate to components 704 attached to a PCB 706. An impinged air 714 from a first impingement plate 718A attached to the duct 716 may contact the components 704 and an exhaust air 702 may leave the PCB 706. The duct 716 may have a smaller thickness 750 at a point shown to accommodate a given component size. The thickness 750 may even be larger than a normal thickness of the duct 716 based on a height of the component 704. The duct 716 may have a first dimension, such as a width or a height or a thickness, varying along a second dimension, such as a length of the duct. A dimension z is a distance between the first impingement plate 718A and a tip of the component 704.

FIG. 15 is a cross-section view of another embodiment of the present disclosure. An apparatus 800 may include a duct 816 having a first impingement plate 818A in proximity to components 804 attached to a PCB 806. The first impingement plate 818A may include a plurality of holes and at least one of the plurality of holes may include a nozzle 860. An exhaust air 802 may leave the PCB 806. In the apparatus 800, the nozzle 860 may be configured to form an angle, such as the angle E shown in FIG. 3, with a plane including the duct 816. The at least one of the plurality of holes may be located on one of a plurality of surfaces of the duct 816, such as a surface proximate to a second PCB in addition to the PCB 806 shown. The second PCB may be opposite to the PCB 806 in an ATCA, for example. In the apparatus 800, the plurality of holes may include a plurality of nozzles 860, each hole may have a nozzle 860, and the plurality of nozzles 860 may be further configured to have one of an identical diameter and a predetermined range of diameters.

In another embodiment of the present disclosure, considering the features and concepts shown in FIGS. 2, 6, and 9-13, an apparatus may include a plenum 220 having a fluid such as input air 210. The plenum 220 may be configured to contact a first plate 222. A duct 216 may have a first surface such as 218A shown in FIG. 2, a second surface such as 218B, a first end 216A and a second end 216B shown in FIG. 6, the first end 216A attached to the first plate 222 and the second end 216B attached to a second plate 222A, wherein the duct 216 may include a plurality of holes 940, 1040, 1140, 1240, and 1340, as shown in FIGS. 9-13, on at least one of the first surface such as 218A and the second surface such as 218B, the plurality of holes 940, 1040, 1140, 1240, and 1340 may have a predetermined size, a predetermined shape, a predetermined distribution (as indicated by distances 942, 944 in FIG. 9, distances 1042, 1044 in FIG. 10, distances 1142, 1144 in FIG. 11, distances 1242A, 1242B, 1244A, 1244B in FIG. 12, and distances 1342,1344 in FIG. 13) on the at least one of the first surface such as 218A and the second surface such as 218B, and the plurality of holes 940, 1040, 1140, 1240, and 1340 may be configured to pass the fluid such as input air 210. An electric component 204 may be attached to a printed circuit board, such as the electric circuit substrate 206A, 206B, located at a predetermined distance from the plurality of holes 940, 1040, 1140, 1240, and 1340, and the plurality of holes 940, 1040, 1140, 1240, and 1340 may be configured to direct the input air 210 onto the electric component 204. In the aforementioned apparatus, as shown in FIG. 2, the duct 216 may be located between a first PCB 206A and a second PCB 206B, the first surface such as 218A of the duct 216 being proximate to the first PCB 206A and the second surface such as 218B being proximate to the second PCB 206B. The duct 216 may have a thickness varying in a predetermined manner along a dimension of the duct 216. Based on cooling requirements for a PCB 206, the first PCB 206A, and the second PCB 206B having components 204, the thickness of the duct 216 at one or more locations may be increased or diminished. Based on a component height at one or more locations on the PCB 206, the first PCB 206A, and the second PCB 206B having components 204, the thickness of the duct 216 may be increased or diminished. In the aforementioned apparatus, at least one of the plurality of holes 940, 1040, 1140, 1240, and 1340 shown in FIGS. 9-13 may include a nozzle 860 as shown in FIG. 15.

In the abovementioned embodiment, the apparatus may include a plurality of heat sources 204 attached to an electric circuit substrate 206, the electric circuit substrate 206 may be oriented at an angle with respect to a direction of a flow of the fluid, such as the input air 210 or the exhaust air 202. The input air 210 may be coupled to one of a compressor and a fan. The input air 210 or the exhaust air 202 may have an intermittent flow. The intermittent flow may be accomplished by throttling the plenum 220, or the duct 216, or a hole (such as hole 224 shown in FIG. 6), or a nozzle (such as nozzle 860 shown in FIG. 15). The apparatus may include the fluid, such as the input air 210, to be coupled to a controller (not shown). The controller may be configured to direct the fluid to a part of an electric circuit substrate 206 having one or more heat sources 204 in response to a change in a temperature of the part of the electric circuit substrate 206.

In another embodiment of the present disclosure, considering the features and concepts shown in FIGS. 2, 6, 9-15, and 19-20, an apparatus may include a plenum 220 having a fluid such as an input air 210. The plenum 220 may be configured to contact a first plate 222. A plurality of ducts 216 may be configured to be attached to the first plate 222, wherein each of the plurality of ducts 216 may have a first surface 218A, a second surface 218B (FIG. 2), a first end 216A, and a second end 216B (FIG. 6). The first end 216A may be attached to the first plate 222 and the second end 216B may be attached to a second plate 222A, wherein a fan 208 (FIG. 2) may be attached to one of the first plate 222 and the second plate 222A. The each of the plurality of ducts 216 may include a plurality of holes 940, 1040, 1140, 1240, and 1340, as shown in FIGS. 9-13, on at least one of the first surface 218A and the second surface 218B, and the plurality of holes 940, 1040, 1140, 1240, and 1340 may be configured to pass the fluid, such as the input air 210.

A plurality of circuit boards 206 may be configured to be attached to at least one of the first plate 222 and the second plate 222A (FIG. 6), wherein each of the plurality of circuit boards 206 may be configured to include an electric component 204. Each of the plurality of circuit boards 206 may be configured to be located at a predetermined distance from the plurality of ducts 216 in use such that the plurality of ducts 216 may be slideably engaged with at least one of the plurality of circuit boards 206 such that one of the plurality of ducts 216 may be disposed between two of the plurality of circuit boards 206. The plurality of holes 940, 1040, 1140, 1240, and 1340 may be configured to direct the fluid, such as the input air 210, onto the electric component 204.

In the aforementioned embodiment, the plurality of holes 940, 1040, 1140, 1240, and 1340 may have at least one of a predetermined size on at least one of the first surface 218A and the second surface 218B, a predetermined shape on at least one of the first surface 218A and the second surface 218B, and a predetermined distribution on at least one of the first surface 218A and the second surface 218B, In the aforementioned embodiment, the plurality of circuit boards 206 may be oriented at an angle with respect to a direction of a flow of the fluid, such as the input air 210 or the exhaust air 202.

In the aforementioned embodiment, the fluid, such as the input air 210, may be coupled to a compressor (not shown). In the aforementioned embodiment, the fluid, such as the input air 210, may have an intermittent flow. The input air 210 or the exhaust air 202 may have an intermittent flow. The intermittent flow may be accomplished by throttling the plenum 220, or the duct 216, or a hole (such as hole 224 shown in FIG. 6), or a nozzle (such as nozzle 860 shown in FIG. 15).

In the aforementioned embodiment, the fluid, such as the input air 210 or the exhaust air 202, may be coupled to a controller (not shown). The controller may be configured to direct the fluid to a part of the circuit board 206 including the electric component 204 in response to a change in a temperature of the part of the circuit board 204 including the electric component 206.

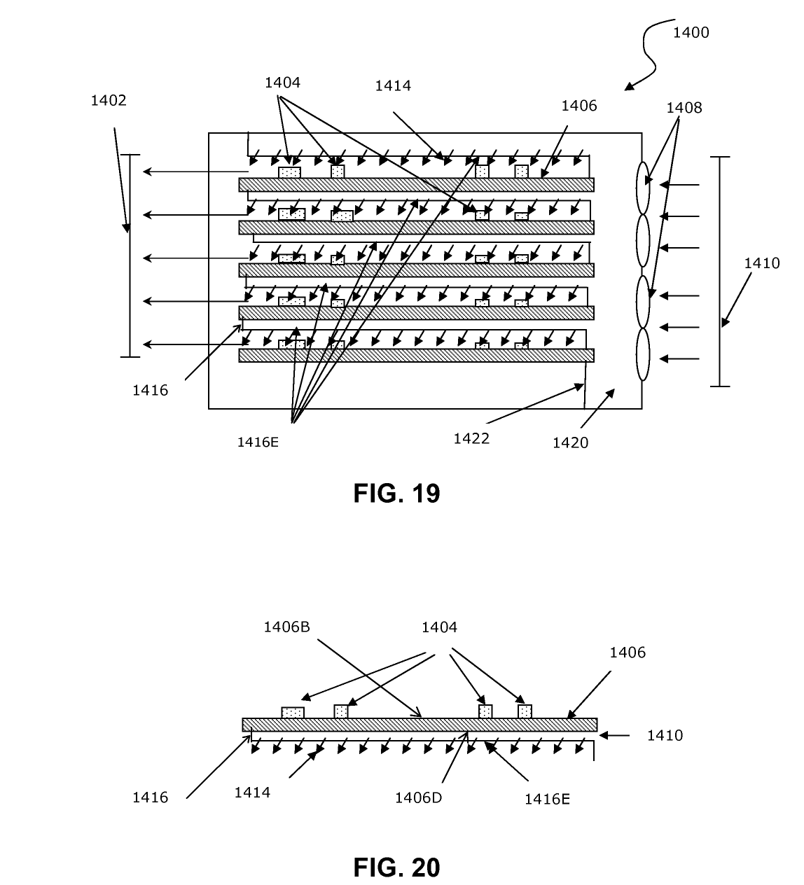

In the aforementioned embodiment, the first surface 218A (FIG. 2) of at least one of the each of the plurality of ducts 216 may be a duct plate 1416E (FIGS. 19 and 20) and the second surface 218B (FIG. 2) of at least one of the each of the plurality of ducts 216 may be a first surface 1406D (FIG. 20) of one of the plurality of circuit boards 1406. A first dimension of the duct plate 1416E may vary along a second dimension of the duct plate 1416E. The first dimension of the duct plate 1416E may be a length and the second dimension of the duct plate 1416E may be a width.

In the aforementioned embodiment, the circuit board 1406 may be coupled to one of a heat pipe and a vapor chamber. Further, the electric component 1404 may be conduction coupled to a circuit board 1406 of the plurality of circuit boards 1406.

In the aforementioned embodiment, one of the plurality of ducts 216 (FIG. 2) may have a first dimension varying along a second dimension of the one of the plurality of ducts 216. The first dimension of one of the plurality of ducts 216 may be a length and the second dimension of one of the plurality of ducts 216 may be a width.

In the aforementioned embodiment, one of the plurality of holes 940, 1040, 1140, 1240, and 1340, as shown in FIGS. 9-13, may be at an angle E (FIG. 3) with respect to a plane P of one of the plurality of ducts 216.

In the aforementioned embodiment, one of the plurality of holes 940, 1040, 1140, 1240, and 1340, may have at least one of a predetermined size, a predetermined shape, and a predetermined interval between two holes of the plurality of holes 940, 1040, 1140, 1240, and 1340. At least one of the plurality of holes 940, 1040, 1140, 1240, and 1340 may include a nozzle 860 (FIG. 15) configured to form an angle E (FIG. 3) with respect to a plane P of one of the plurality of ducts 216.

In another embodiment of the present disclosure, an apparatus may include one or more compressors coupled to at least one of an input air 210 and an exhaust air 202, and one or more valves included in one or more ducts 216. Alternatively, the one or more valves may be located between the one or more compressors and the plenum 220. The one or more valves may close at a predetermined frequency for a predetermined cooling effect. The one or more valves may close at a predetermined duty cycle for a predetermined cooling effect. The one or more valves may be set manually. The one or more valves may be set automatically, such as a smart controller acting in response to a temperature of an electric component 204 to control the one or more valves.

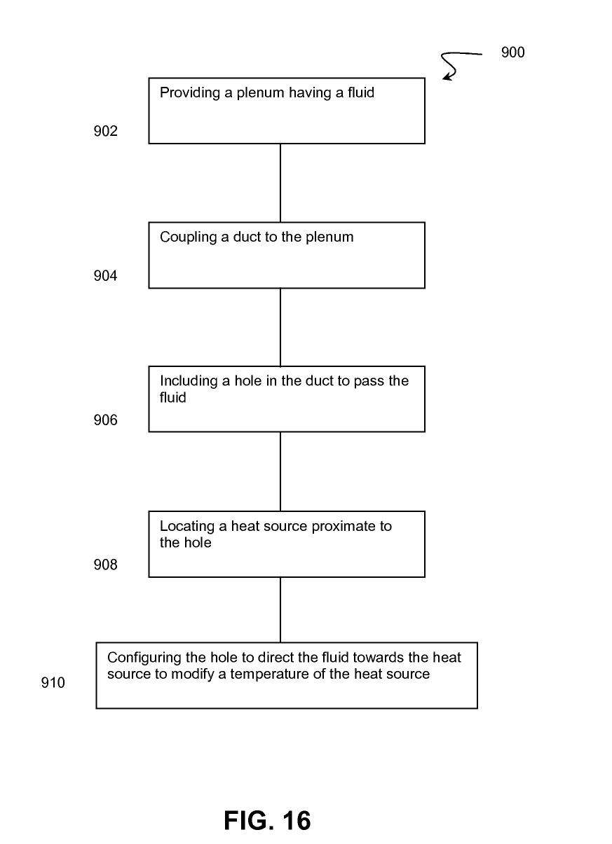

FIG. 16 is a flowchart of an embodiment of a method 900 of the present disclosure. The method 900 may include providing a plenum having a fluid (block 902), coupling a duct to the plenum (block 904), including a hole in the duct to pass the fluid (block 906), locating a heat source proximate to the hole (block 908), and configuring the hole to direct the fluid towards the heat source to modify a temperature of the heat source (block 910). In the method 900, the locating the heat source may further include locating the heat source on an electric circuit substrate. In the method 900, the configuring the hole may further include predetermining at least one of features of a plurality of holes selected from: a shape of the plurality of holes, a size of the plurality of holes, a distribution of the plurality of holes on the duct, and a distance between the plurality of holes and the heat source. In the method 900, the configuring the hole to direct the fluid may further include causing an intermittent flow of the fluid.

As a person having ordinary skill in the art would appreciate, the elements or blocks of the methods described above could take place at the same time or in an order different from the described order.

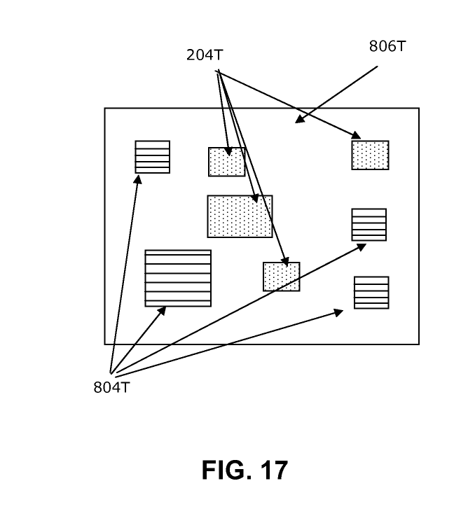

FIG. 17 is an experimental setup for the present disclosure. To verify a higher efficacy of an impingement airflow compared to conventional parallel airflow, a slot in an ATCA chassis was used to conduct an experiment. An effect of heat removal for a multiple jet impingement with different nozzle shapes on the ATCA chassis was tested. The experiment included studying a performance of nozzle geometry, an empirical correlation for heat transfer as related to a preferred nozzle geometry, and obtaining optimized values for a distance between an impingement plate and target plate, such as a PCB, a size of impingement hole(s), a space between the holes, and a preferred number of the holes.

Simulated components 204T were made of Aluminum blocks. Kapton® tape heaters were attached to the bottom of the simulated components 204T using double adhesive tapes. Kapton® tape heaters were attached to the board 806T using a double adhesive tape.

Additional heat sinks 804T, including attached heaters (not shown) beneath heat sinks 804T, with a range of sizes were assembled to the board 806T. The board 806T may be made of FR4 known in the art and simulates a PCB. FIG. 17 is an exemplary setup. In a given setup, there may be fewer or more points for temperature monitoring. By adjusting a voltage to the heaters beneath the heat sinks 804T and the simulated components 204T, a power dissipation of each heater may be calculated by knowing a resistance and a current flow. Holes (not shown) were also drilled at a base of the heat sinks 804T and the simulated components 204T for inserting thermocouples to measure the simulated component 204T temperature or heat sink 804T temperature. A fan voltage was also varied by changing the voltage from the power supply to control the volumetric flow rate over the board 806T. Thermocouples (not shown) were attached to different locations of the board 806T, as well as to simulated components 204T and heat sinks 804T, to measure a board 806T temperature.

Various nozzle shapes such as circular, triangular, star, snowflake, perforated plate, and rectangular, were used to find out the preferred nozzle geometry and an optimized nozzle size and an optimum Nusselt number. The data were correlated according to the empirical equation

$${Nu}_{{D}_{h}} = C {{Re}_{{D}_{h}}^{m} ( \frac{z}{{D}_{h}} )}^{n} {( \frac{S}{{D}_{h}} )}^{p}$$

where C, m, n, and p are constants. Re_{D}_{ₕ} is a Reynolds number, z is a distance (FIG. 14) between an impingement plate and a tip of heat sink 804T fins or a point of the simulated components 204T, S is a distance between holes, and Dₕ is a hydraulic diameter.

A preferred heat transfer performance for impingement may be dependent on a distance between an impingement plate and a target plate (such as the PCB) z (FIG. 14), hydraulic diameter of holes, Dₕ, the distance between holes, S, assuming the holes are substantially equally spaced. The distance between holes, S, may be as described in 942, 944, 1042, 1044, 1142, 1144, 1242A, 1242B, 1244A, 1244B, 1342, and 1342, as shown in FIGS. 9-13.

Based on the experiment, optimized values of impingement parameters in a cross flow case were found. The cross flow referred to here may be a flow of an impinged air 214 (FIG. 2) turning to flow along a plane of the PCB 206 (FIG. 2). Temperature values of the components were collected for various shapes and size of hole(s) and hole-to-target (PCB) spacing and the optimized values were determined.

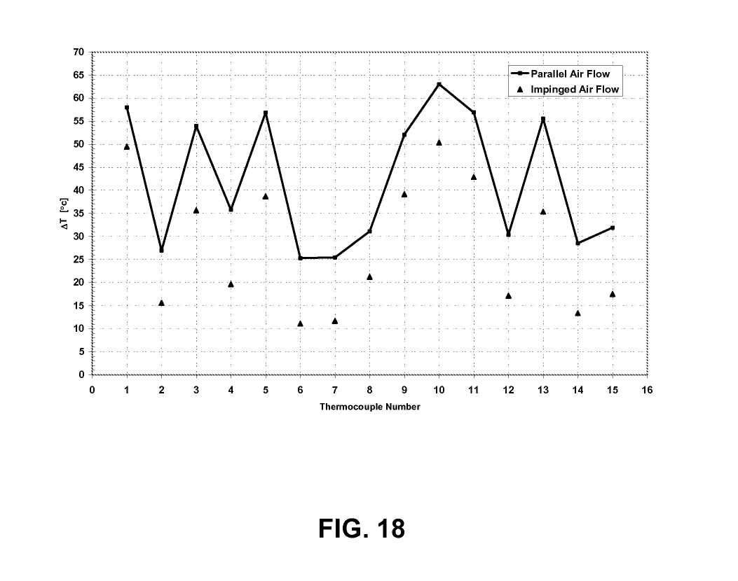

FIG. 18 is a plot of a result of an exemplary test setup similar to that featured in FIG. 17 showing an improvement from the impingement airflow cooling compared to conventional parallel airflow cooling. Simulated components with attached heaters were installed on the PCB and powered by a power supply. Temperature data were collected for both cases of impingement airflow and parallel airflow. The fan voltage was kept fixed between the two cases. FIG. 18 shows the temperature rise, ΔT or component 204T or board 806T temperature minus ambient temperature or board 806T minus ambient temperature or heat sink 804T minus ambient temperature, on a y-axis for 15 thermocouple numbers representing simulated components 204T, board 806T locations, and heat sinks 804T on an x-axis. A solid line connecting circular points shows the data for parallel airflow cooling and the triangular points show the data for the impingement airflow cooling. The data shows an improvement of approximately 13%-53% for the simulated components.

FIG. 19 is a cross-section view of another embodiment of the present disclosure. FIG. 19 illustrates a system 1400 which may include a plenum 1420. The plenum 1420 may be in contact with a plate 1422. Duct plates 1416E having at least one hole may be attached to a system 1400 backplane (not shown) to create an air duct 1416. Duct plates 1416E having at least one hole may be attached to one or more PCBs 1406 having components 1404 attached to the PCBs 1406. An input air 1410 may be drawn into the plenum 1420. The input air 1410 may pass through the holes on the duct plates 1416E. The input air 1410 may be assisted by fan 1408 possibly attached to the plate 1422. The input air 1410 may create an impinged air 1414 contacting the PCBs 1406 and the components 1404. An exhaust air 1402 leaves the PCBs 1406 and the components 1404.

FIG. 20 is a view of a portion of FIG. 19. The duct 1416 may be formed between a first surface 1406D of the PCB 1406 and the duct plate 1416E. The components 1404 may reside on a second surface 1406B of the PCB 1406 as shown. Input air 1410 may go into the duct 1416 which may be formed between the first surface 1406D of the PCB 1406 and duct plate 1416E. The duct plate 1416E may create the impinged air 1414 from one or more holes formed on the duct plate 1416E.

As used in this specification and appended claims, the singular forms “a,” “an,” and “the” include plural referents unless the specification clearly indicates otherwise. The term “plurality” includes two or more referents unless the specification clearly indicates otherwise. Further, unless described otherwise, all technical and scientific terms used herein have meanings commonly understood by a person having ordinary skill in the art to which the disclosure pertains.

It should be emphasized that the above-described embodiments are merely some possible examples of implementation, set forth for a clear understanding of the principles of the disclosure. Many variations and modifications may be made to the above-described embodiments of the invention without departing substantially from the principles of the invention. All such modifications and variations are intended to be included herein within the scope of this disclosure and the present invention and protected by the following claims.

What is claimed is:

1. An apparatus comprising:
a plenum having a fluid, the plenum configured to contact a plate;
a duct attached to the plate, wherein the duct includes a hole configured to pass the fluid;
a heat source located proximate to the hole; and
the hole being configured to make a contact between the fluid and the heat source.

2. The apparatus of claim 1, wherein the apparatus includes a plurality of ducts attached to the plate.

3. The apparatus of claim 1, wherein the duct includes a plurality of holes.

4. The apparatus of claim 1, wherein the fluid is one of an air and a gas.

5. The apparatus of claim 1, wherein the apparatus includes a plurality of heat sources attached to an electric circuit substrate, the electric circuit substrate being located at a predetermined distance from the duct.

6. The apparatus of claim 5, wherein the electric circuit substrate is coupled to one of a heat pipe and a vapor chamber.

7. The apparatus of claim 5, wherein an electric component is conduction coupled to the electric circuit substrate.

8. The apparatus of claim 1, wherein the duct comprises at least one impingement plate.

9. The apparatus of claim 8, wherein the at least one impingement plate includes at least one hole.

10. The apparatus of claim 1, further comprising a first duct configured to cause a flow of the fluid in a direction towards the plate and a second duct configured to cause a flow of the fluid in a direction away from the plate.

11. The apparatus of claim 1, wherein the duct comprises a first end and a second end, wherein the first end is attached to a first plate and the second end is attached to a second plate, and wherein the first plate is coupled to the second plate.

12. The apparatus of claim 1, wherein the duct has a first dimension varying along a second dimension of the duct.

13. The apparatus of claim 12, wherein the first dimension is a thickness and the second dimension is a length.

14. The apparatus of claim 1, wherein the hole is at an angle with respect to a plane of the duct.

15. The apparatus of claim 1, wherein the hole has one of a predetermined size and a predetermined shape.

16. The apparatus of claim 1, wherein the duct includes a plurality of holes, the plurality of holes having a plurality of sizes selected from a predetermined range of sizes.

17. The apparatus of claim 16, wherein the plurality of holes are located on the duct at one of an equal interval between the plurality of holes and a variable interval between the plurality of holes.

18. The apparatus of claim 16, wherein at least one of the plurality of holes includes a nozzle.

19. The apparatus of claim 18, wherein the nozzle is configured to form an angle with a plane including the duct.

20. The apparatus of claim 18, wherein the at least one of the plurality of holes is located on one of a plurality of surfaces of the duct.

21. The apparatus of claim 17, wherein the plurality of holes includes a plurality of nozzles, each hole having a nozzle, the plurality of nozzles further configured to have one of an identical diameter and a predetermined range of diameters.

22. The apparatus of claim 1, wherein the apparatus includes a plurality of heat sources attached to an electric circuit substrate, the electric circuit substrate being oriented at an angle with respect to a direction of a flow of the fluid.

23. The apparatus of claim 1, wherein the fluid is coupled to one of a compressor and a fan.

24. The apparatus of claim 1, wherein the fluid has an intermittent flow.

25. The apparatus of claim 1, wherein the fluid is coupled to a controller, the controller being configured to direct the fluid to a part of an electric circuit substrate having one or more heat sources in response to a change in a temperature of the part of the electric circuit substrate.

26. An apparatus comprising:
a plenum having a fluid, the plenum configured to contact a first plate;
a duct having a first surface, a second surface, a first end, and a second end, the first end attached to the first plate and the second end attached to a second plate, wherein the duct includes a plurality of holes on at least one of the first surface and the second surface, the plurality of holes having a predetermined size, a predetermined shape, a predetermined distribution on the at least one of the first surface and the second surface, and the plurality of holes configured to pass the fluid;
an electric component attached to a circuit board located at a predetermined distance from the plurality of holes; and
the plurality of holes being configured to direct the fluid onto the electric component.

27. The apparatus of claim 26, wherein the duct is located between a first circuit board and a second circuit board, the first surface of the duct being proximate to the first circuit board and the second surface being proximate to the second circuit board.

28. The apparatus of claim 26, wherein the duct has a thickness varying in a predetermined manner along a dimension of the duct.

29. The apparatus of claim 26, wherein at least one of the plurality of holes includes a nozzle.

30. The apparatus of claim 26, wherein the apparatus includes a plurality of electric components attached to a plurality of circuit boards, the plurality of circuit boards being oriented at an angle with respect to a direction of a flow of the fluid.

31. The apparatus of claim 26, wherein the fluid is coupled to one of a compressor and a fan.

32. The apparatus of claim 26, wherein the fluid has an intermittent flow.

33. The apparatus of claim 26, wherein the fluid is coupled to a controller, the controller being configured to direct the fluid to a part of the circuit board having one or more circuit components in response to a change in a temperature of the part of the circuit board.

34. A method comprising:
providing a plenum having a fluid;
coupling a duct to the plenum;
including a hole in the duct to pass the fluid;
locating a heat source proximate to the hole; and
configuring the hole to direct the fluid towards the heat source to modify a temperature of the heat source.

35. The method of claim 34, wherein the locating the heat source further comprises locating the heat source on an electric circuit substrate.

36. The method of claim 34, wherein the configuring the hole further comprises predetermining at least one of features of a plurality of holes selected from the group consisting of:
a shape of the plurality of holes,
a size of the plurality of holes,
a distribution of the plurality of holes on the duct, and
a distance between the plurality of holes and the heat source.

37. The method of claim 34, wherein the configuring the hole to direct the fluid further comprises causing an intermittent flow of the fluid.

38. An apparatus comprising:
a plenum having a fluid, the plenum configured to contact a first plate;
a plurality of ducts configured to be attached to the first plate, wherein each of the plurality of ducts has a first surface, a second surface, a first end, and a second end, the first end attached to the first plate and the second end attached to a second plate, wherein a fan is attached to one of the first plate and the second plate and the each of the plurality of ducts includes a plurality of holes on at least one of the first surface and the second surface, and the plurality of holes is configured to pass the fluid;
a plurality of circuit boards configured to be attached to at least one of the first plate and the second plate, wherein each of the plurality of circuit boards is configured to include an electric component and each of the plurality of circuit boards is configured to be located at a predetermined distance from the plurality of ducts in use such that the plurality of ducts is slideably engaged with at least one of the plurality of circuit boards such that one of the plurality of ducts is disposed between two of the plurality of circuit boards; and
the plurality of holes being configured to direct the fluid onto the electric component.

39. The apparatus of claim 38 wherein the plurality of holes have at least one of a predetermined size, a predetermined shape, and a predetermined distribution on at least one of the first surface and the second surface,

40. The apparatus of claim 38, wherein the plurality of circuit boards is oriented at an angle with respect to a direction of a flow of the fluid.

41. The apparatus of claim 38, wherein the fluid is coupled to a compressor.

42. The apparatus of claim 38, wherein the fluid has an intermittent flow.

43. The apparatus of claim 38, wherein the fluid is coupled to a controller, the controller being configured to direct the fluid to a part of the circuit board including the electric component in response to a change in a temperature of the part of the circuit board including the electric component.

44. The apparatus of claim 38, wherein the first surface of at least one of the each of the plurality of ducts is a duct plate and the second surface of at least one of the each of the plurality of ducts is a first surface of one of the plurality of circuit boards.

45. The apparatus of claim 38, wherein the circuit board is coupled to one of a heat pipe and a vapor chamber.

46. The apparatus of claim 38, wherein the electric component is conduction coupled to a circuit board of the plurality of circuit boards.

47. The apparatus of claim 38, wherein one of the plurality of ducts has a first dimension varying along a second dimension of the one of the plurality of ducts.

48. The apparatus of claim 38, wherein one of the plurality of holes is at an angle with respect to a plane of one of the plurality of ducts.

49. The apparatus of claim 38, wherein one of the plurality of holes has at least one of a predetermined size, a predetermined shape, and a predetermined interval between two holes of the plurality of holes.

50. The apparatus of claim 38, wherein at least one of the plurality of holes includes a nozzle configured to form an angle with a plane including one of the plurality of ducts.
